(19) United States
(12) Patent Application Publication
(10) Pub. No.: US 2025/0308886 A1
(43) Pub. Date: Oct. 2, 2025

(54) GAP FILLING BY ATOMIC LAYER DEPOSITION (ALD)

(71) Applicant: Tokyo Electron Limited, Tokyo (JP)

(72) Inventors: Toshihiko IWAO, Nirasaki City (JP); Jianping ZHAO, Austin, TX (US)

(73) Assignee: Tokyo Electron Limited, Tokyo (JP)

(21) Appl. No.: 18/620,004

(22) Filed: Mar. 28, 2024

(51) Int. Cl. H01L 21/02; C23C 16/455; C23C 16/52

(52) U.S. Cl. CPC H01L 21/0228; C23C 16/45536; C23C 16/52; H01L 21/02274; H01L 21/02123

(57) ABSTRACT

A method of manufacturing a semiconductor device is provided. The method includes providing a wafer including a patterned structure having a top, a bottom and a sidewall. A film can be formed on the wafer by a cyclical deposition process including a cycle of contacting the wafer with a first reactant including a silicon precursor to form an intermediate layer over the patterned structure of the wafer, contacting the wafer with a second reactant to form a material layer, and generating a second plasma including an inert gas species to modify the material layer by delivering the inert gas species anisotropically towards the top of the patterned structure. The silicon precursor includes a silicon-halogen bond. The second reactant includes a precursor generated by a first plasma and selected from the group consisting of a nitrogen precursor, an oxygen precursor and a carbon precursor.

### FIELD OF THE INVENTION

This disclosure relates generally to methods of microfabrication and more specifically to film deposition.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area and yet are running into greater challenges as miniaturization continues with three-dimensional (3D) semiconductor structure and topography.

### SUMMARY

The present disclosure relates to a method of manufacturing a semiconductor device and an apparatus of executing the same.

According to a first aspect of the disclosure, a method of manufacturing a semiconductor device is provided. The method includes providing a wafer including a patterned structure having a top, a bottom and a sidewall. A film can be formed on the wafer by a cyclical deposition process including a cycle of contacting the wafer with a first reactant including a silicon precursor to form an intermediate layer over the patterned structure of the wafer, contacting the wafer with a second reactant to form a material layer, and generating a second plasma including an inert gas species to modify the material layer by delivering the inert gas species anisotropically towards the top of the patterned structure. The silicon precursor includes a silicon-halogen bond. The second reactant includes a precursor generated by a first plasma and selected from the group consisting of a nitrogen precursor, an oxygen precursor and a carbon precursor.

In some embodiments, the silicon precursor includes a chlorosilane represented by a formula of SiₙHₓCl_{y}. n is 1, 2, 3 or 4. x is an integer of 0 or more. y is an integer of 1 or more. x+y=2n+2.

In some embodiments, the silicon precursor includes at least one selected from the group consisting of H₃SiCl, dichlorosilane (DCS), tetrachlorosilane, pentachlorodisilane (PCDS), hexachlorodisilane (HCDS) and octachlorotrisilane.

In some embodiments, the cycle further includes generating a third plasma including nitrogen ions to modify the material layer by delivering the nitrogen ions isotropically towards the patterned structure.

In some embodiments, the nitrogen ions are configured to densify and shrink the film.

In some embodiments, the cycle further includes repeating for at least one more time: generating the second plasma and generating the third plasma.

In some embodiments, the third plasma further includes argon (Ar).

In some embodiments, the second plasma includes helium (He), and the inert gas species includes He⁺ ions, He* radicals or a combination thereof.

In some embodiments, the inert gas species is substantially unidirectional and substantially perpendicular to the top of the patterned structure.

In some embodiments, the inert gas species is configured to suppress film deposition at the top of the patterned structure.

In some embodiments, the inert gas species is configured to suppress film deposition at the top of the patterned structure without suppressing film deposition at the bottom of the patterned structure.

In some embodiments, the second plasma includes no nitrogen.

In some embodiments, the second reactant includes N₂H₂, NF₃, NH₃, N₂H₄ or a combination of N₂ and H₂.

In some embodiments, the cyclical deposition process includes atomic layer deposition.

In some embodiments, the cyclical deposition process includes repeating the cycle for at least one more time.

In some embodiments, the film is thinner at the top of the patterned structure than at the bottom and the sidewall of the patterned structure.

In some embodiments, the patterned structure of the wafer includes at least one surface group selected from the group consisting of —SiH, —SiOH and —SiNH₂.

In some embodiments, the material layer includes one selected from the group consisting of silicon nitride, silicon oxide, silicon oxynitride and silicon carbide.

In some embodiments, the top and the bottom of the patterned structure are substantially parallel to each other, and a ratio of a depth of the patterned structure to a width of the bottom is in a range of 3 to 20.

According to a second aspect of the disclosure, an apparatus is provided. The apparatus includes a controller including a processor that is programmed to provide a wafer including a patterned structure having a top, a bottom and a sidewall and form a film on the wafer by a cyclical deposition process. The cyclical deposition process includes a cycle of contacting the wafer with a first reactant including a silicon precursor to form an intermediate layer over the patterned structure of the wafer, contacting the wafer with a second reactant to form a material layer, and generating a second plasma including an inert gas species to modify the material layer by delivering the inert gas species anisotropically towards the top of the patterned structure. The silicon precursor includes a silicon-halogen bond. The second reactant includes a precursor generated by a first plasma and selected from the group consisting of a nitrogen precursor, an oxygen precursor and a carbon precursor.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a schematic of a plasma tool in accordance with some embodiments of the present disclosure.

FIG. 1B shows a vertical cross-sectional schematic of a wafer in accordance with some embodiments of the present disclosure.

FIG. 2 shows a block diagram of a film deposition process in accordance with some embodiments of the present disclosure.

FIGS. 3A, 3B, 3C, 3D and 3E show vertical cross-sectional views of a semiconductor device at various intermediate steps of manufacturing, in accordance with some embodiments of the present disclosure.

FIG. 4A shows a schematic of a film deposition process in related examples.

FIG. 4B shows a schematic of a film deposition process in accordance with some embodiments of the present disclosure.

FIG. 5 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the in orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As noted in the Background, scaling efforts are running into greater challenges with three-dimensional (3D) semiconductor structure and topography, especially on the scale of sub-30 nm or even single-digit nanometers. Precise control of film thickness is therefore desirable and crucial. Atomic layer deposition (ALD) is capable of producing very thin, conformal films with control of the thickness and composition of the films possible at the atomic level.

For a 3D topography such as a trench, a hole or a slit, ALD can be used to form one or more films to fill the gap. However, a void or seam is often seen in the ALD film(s) within the filled space. Ideal V-shaped ALD is difficult in terms of effective topological growth inhibition. Very high frequency (VHF) plasma-enhanced ALD (PEALD) can provide conformal films on 3D structure, but it is still difficult to avoid void and seam when filling the gap. Particularly for ALD of silicon nitride (SiN), low temperature SiN gap fill in low hydrogen fluoride-wet etch rate (HF-WER) often comes with the problem of air voids or seams in the filled space.

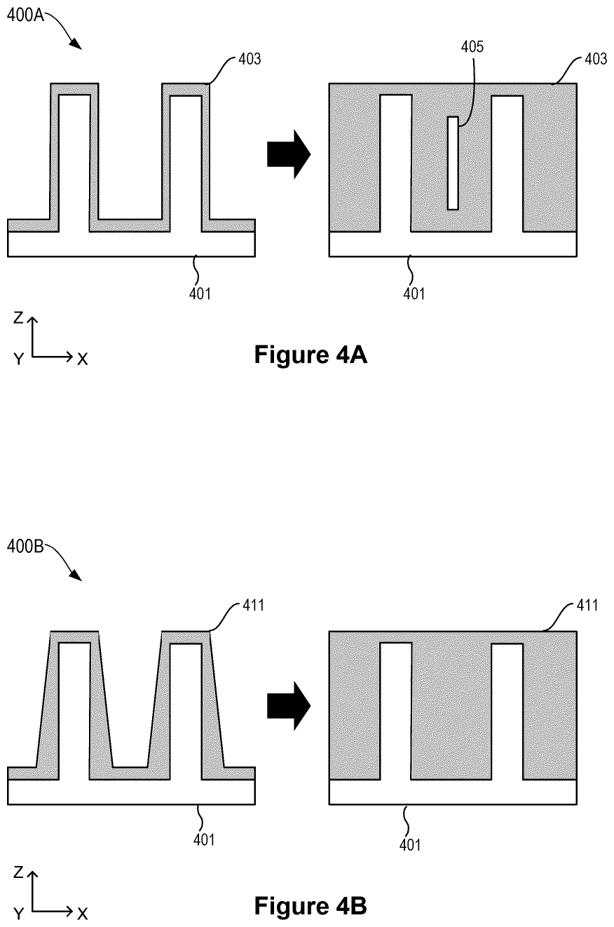

FIG. 4A shows a schematic of a film deposition process in conventional ALD. A conform film 403 can be formed on a substrate 401. However, such conformal growth may result in a void 405 when the gap is filled. FIG. 4B shows a schematic of a film deposition process in accordance with some embodiments of the present disclosure. A non-conformal film 411, which has a thinner top relative to a bottom and sidewalls, can be formed on the substrate 401. Therefore, void formation can be avoided when the gap is filled. In other words, in order to achieve a gap-fill deposition by ALD, effective slowdown around the top surface region is desirable.

Techniques herein enable gap filling with SiN at low temperature without the formation of voids or seams. Particularly, VHF helium plasma can be utilized to remove hydrogen from a silicon surface, and nitrogen ion bombardment can enhance the formation of SiN while lowering the growth rate per ALD cycle. Cyclical helium-and-nitrogen introduction can enhance hydrogen removal and film densification since the helium plasma slows down horizontal film growth while not affecting the sidewall growth.

According to aspects of the disclosure, during the plasma nitridation step of SiN ALD for a single wafer, a first plasma includes hydrogen to provide —NH₂ termination which is favorable for dichlorosilane (DCS) adsorption. At a second plasma step, an inert gas plasma, including helium and excluding nitrogen, is ignited to irradiate directional helium ions to remove hydrogen from only the top (and optionally bottom) horizontal surface. Then after the inert gas plasma, a nitrogen gas is added to a base gas to provide isotropic ions to enhance silicon nitride bridging reaction to densify and shrink the ALD film. The nitrogen gas can be introduced by cyclical pulses.

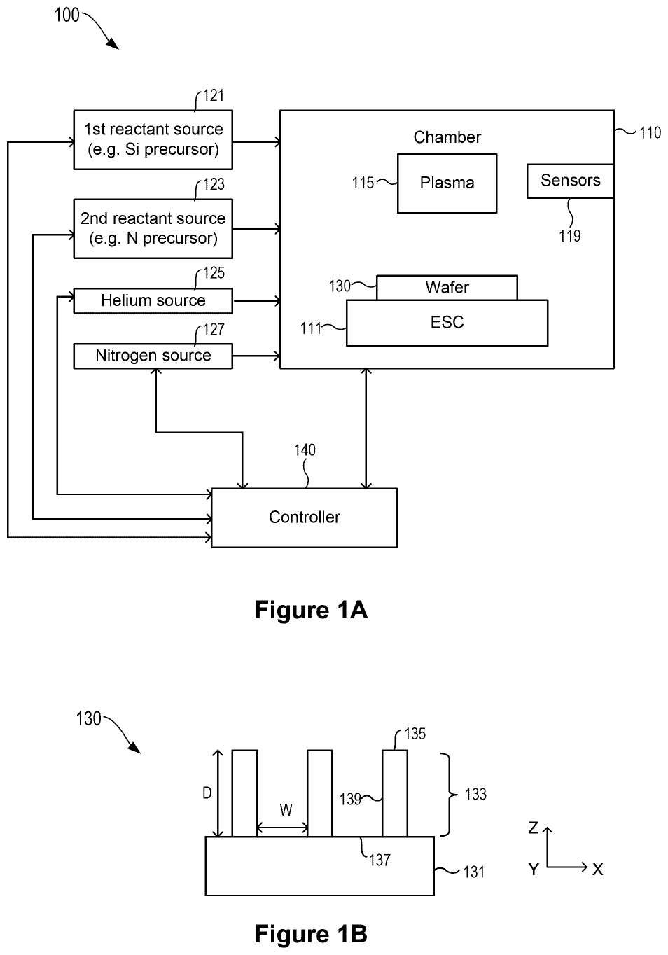

FIG. 1A shows a schematic of a plasma system (referred to as a system 100 hereinafter) in accordance with some embodiments of the present disclosure. As shown, the system 100 includes at least one plasma processing chamber (referred to as a chamber 110 hereinafter). In the chamber 110, a wafer 130 can be placed on an electrostatic chuck (ESC) 111. The chamber 110 can be configured to receive or generate a plasma 115 to process the wafer 130. One or more sensors 119 can be used to characterize/monitor the wafer 130 and/or the plasma 115.

The chamber 110 can be coupled to a first reactant source 121 by conduits, pipes or the like and receive a first reactant (e.g. a silicon precursor) from the first reactant source 121. The first reactant source 121 may be coupled to a manifold, valve control system, mass flow control system or the like to release the first reactant in a gaseous form. In some embodiments, the first reactant is liquid or solid under room temperature and standard atmospheric pressure conditions and can be vaporized within a reactant source vacuum vessel, which may be maintained at or above a vaporizing temperature within a precursor source chamber. Accordingly, the vaporized precursor may be transported with a carrier gas (e.g. an inactive or inert gas) and then fed into the chamber 110 through a conduit. In other embodiments, the first reactant may be a vapor under standard conditions. Accordingly, the first reactant may be stored in a gas cylinder and need no carrier gas.

Similarly, the chamber 110 can be coupled to a second reactant source 123 and receive a second reactant (e.g. a nitrogen precursor) from the second reactant source 123. Additionally, the chamber 110 can be coupled to a helium source 125, a nitrogen source 127, a carrier gas source, an inert gas source, a purge gas source and/or the like (not all shown for simplicity purposes). Similar descriptions have been provided above for first reactant source 121 and will be omitted herein for simplicity purposes.

In a non-limiting example, the system 100 is configured to execute atomic layer deposition (ALD) of silicon nitride (SiN) on the wafer 130. Accordingly, the first reactant source 121 and the second reactant source 123 respectively include a silicon precursor and a nitrogen precursor. The nitrogen precursor can include, but are not limited to, N₂, NH₃, N₂H₄, N₂H₂, NF₃ and combinations thereof.

The silicon precursor can include a silicon-halogen bond. For instance, the silicon precursor can include a chlorosilane represented by a formula of SiₙHCl_{y}, where n is 1, 2, 3 or 4, x is an integer of 0 or more, y is an integer of 1 or more, preferably 2 or more, and x+y=2n+2. Examples include, but are not limited to, monochlorosilane (MCS) such as H₃SiCl, dichlorosilane (DCS), tetrachlorosilane, pentachlorodisilane (PCDS), hexachlorodisilane (HCDS) and octachlorotrisilane. Examples of the silicon precursor discussed herein can be used individually or in any combination.

Further, the chamber 110 can be coupled to the helium source 125 and receive a helium-containing gas from the helium source 125. The helium-containing gas can be used to generate a helium plasma in the chamber 110 which contains He⁺ ions, He* radicals or both. The helium plasma can be substantially unidirectional and contain no nitrogen.

In addition, the chamber 110 can be coupled to the nitrogen source 127 and receive a nitrogen-containing gas from the nitrogen source 127. The nitrogen-containing gas may further contain an inert gas such as argon. The nitrogen-containing gas can be used to generate a nitrogen plasma in the chamber 110. The nitrogen plasma can be substantially isotropic.

In some embodiments, the second reactant source 123, the helium source 125 and/or the nitrogen source 127 can each independently include a respective remote plasma source, from which the chamber 110 receives a respective plasma. In some embodiments, the nitrogen source 127 may be implemented as part of the second reactant source 123 for instance when the second reactant source 123 includes nitrogen gas.

Additionally, the sensors 119 can include an optical emission spectroscopy (OES) sensor, a voltage peak-to-peak (VPP) sensor, an ion flux sensor, a mass spectrometer, a temperature sensor, a pressure sensor, a reflectometer, an ellipsometer and/or other sensors as known by one skilled in the art. While shown to be installed on a sidewall of the chamber 110 in the example of FIG. 1A, locations of the sensors 119 are not particularly limited. That is, the sensors 119 can each independently be placed inside or outside the chamber 110, in contact with, in proximity to, distant from or within the wafer 130, and the like.

Further, a controller 140 may optionally be included in the example of FIG. 1A. Components of one or more corresponding plasma tools can be connected to and controlled by the controller 140 that may optionally be connected to a corresponding memory storage unit and user interface (all not shown for simplicity purposes). Various plasma-processing operations can be executed via the user interface, and various plasma processing recipes and operations can be stored in a storage unit. Accordingly, a given wafer can be processed within a plasma chamber with various microfabrication techniques.

The controller 140 may be coupled to various components of the corresponding plasma tool(s) to receive inputs from and provide outputs to the components. For example, the controller 140 can be configured to receive sensor data from the sensors 119 to monitor gas species and/or the wafer 130 in the chamber 110 and determine flow rates of precursors. The controller 140 can also be configured to adjust knobs and control settings for the corresponding plasma tool(s), or more specifically the chamber 110, the first reactant source 121, the second reactant source 123, the helium source 125 and the nitrogen source 127. Of course the adjustment(s) can be manually made as well.

The controller 140 can be implemented in a wide variety of manners. In one example, the controller 140 is a computer. In another example, the controller 140 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

Note that the system 100 may include a capacitively-coupled plasma processing apparatus, inductively coupled plasma processing apparatus, microwave plasma processing apparatus, electron cyclotron resonance (ECR) plasma processing apparatus, or other types of processing systems or combination of systems. Thus, it will be recognized by those skilled in the art that the techniques described herein may be utilized with any of a wide variety of plasma processing systems. The system 100 can be used for a wide variety of operations including, but not limited to, etching, deposition, cleaning, plasma polymerization, plasma-enhanced chemical vapor deposition (PECVD), atomic layer deposition (ALD), atomic layer etching (ALE), and the like. Particularly, ALD is used in this disclosure for illustrative purposes and is not limiting. Structures of plasma tools and ALD tools are both well known to one skilled in the art. It will be recognized that different and/or additional plasma process systems may be implemented while still taking advantage of the techniques described herein.

FIG. 1B shows a vertical cross-sectional schematic of the wafer 130 in accordance with some embodiments of the present disclosure. As illustrated, the wafer 130 can include a substrate 131 and a patterned structure 133 formed thereon. The patterned structure 133 can have a top 135, a bottom 137 and a sidewall 139. The top 135 and the bottom 137 of the patterned structure 133 are substantially parallel to each other. The patterned structure 133 can include a trench, a hole, a slit, a gap, an opening or any other topography that has a vertical cross-sectional view as shown. For example, the patterned structure 133 can include parallel lines of material (e.g. metal and/or dielectric) with gaps in between. The patterned structure 133 can have a high aspect ratio in that a ratio of a depth D of the patterned structure 133 to a width W of the bottom 137 is in a range of 3 to 20, such as 3, 5, 7, 10, 12, 15, 18, 20 or any value therebetween.

In one embodiment, the substrate 131 and the patterned structure 133 include different materials. The wafer 130 may further include one or more layers (not shown) formed between the substrate 131 and the patterned structure 133. In another embodiment, the substrate 131 and the patterned structure 133 include the same material. The substrate 131 and the patterned structure 133 can therefore be a monolithic piece. Regardless of the chemical composition of the substrate 131 and the patterned structure 133, the patterned structure 133 can be treated to have surface groups such as —SiH, —SiOH and —SiNH₂. In a non-limiting example, the substrate 131 includes silicon while the patterned structure 133 includes —NH₂ surface groups on the top 135, the bottom 137 and the sidewall 139. The material of the patterned structure 133 is not particularly limited and can include, but is not limited to, silicon, silicon oxide, silicon nitride, silicon oxynitride and silicon carbide.

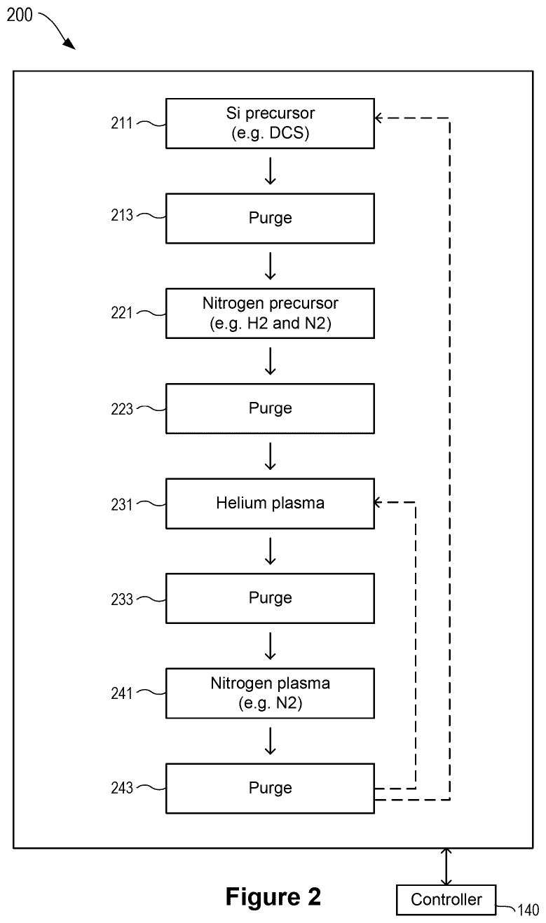

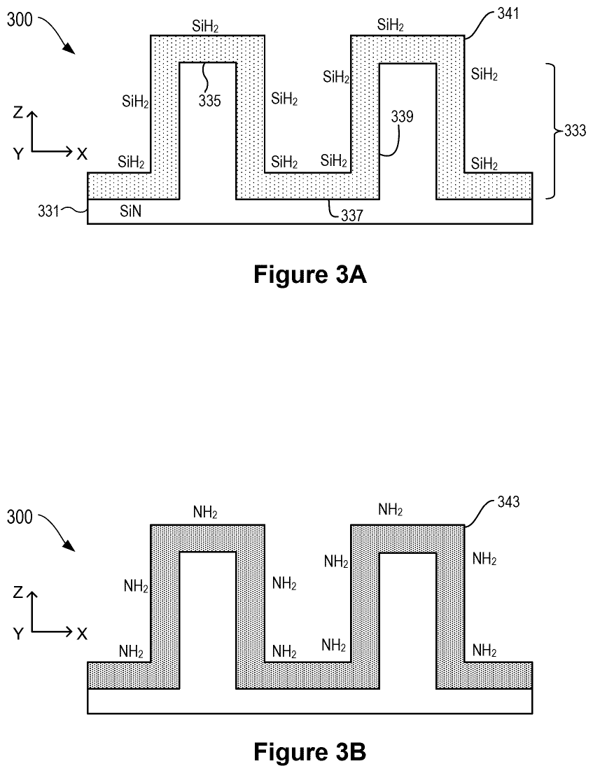

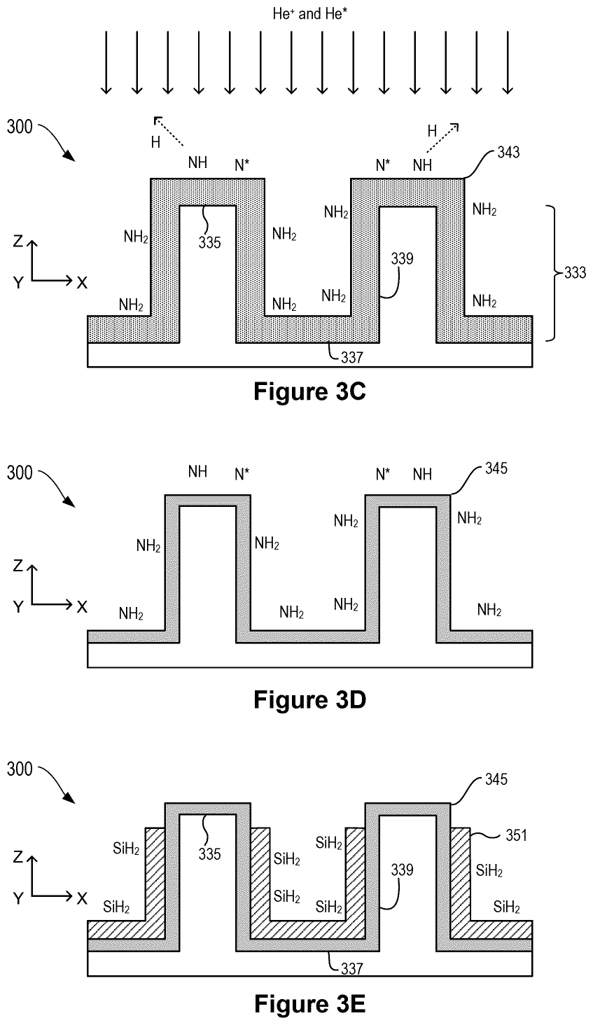

FIG. 2 shows a block diagram of a process 200 of atomic layer deposition (ALD) of silicon nitride (SiN), and FIGS. 3A, 3B, 3C, 3D and 3E show vertical cross-sectional views of a semiconductor device 300 at various intermediate steps of manufacturing in accordance with some embodiments of the present disclosure. The process 200 can be executed by the system 100 and the like.

In block 211, the aforementioned silicon precursor is introduced into the chamber 110 as the first reactant. Dichlorosilane (DCS) will be used herein as one example of the silicon precursor for illustrative purposes.

For example in FIG. 3A, the semiconductor device 300 can include a substrate 331 and a patterned structure 333 formed thereon. The patterned structure 333 can have a top 335, a bottom 337 and a sidewall 339. The substrate 331, the patterned structure 333, the top 335, the bottom 337 and the sidewall 339 can respectively correspond to the substrate 131, the patterned structure 133, the top 135, the bottom 137 and the sidewall 139. Descriptions have been provided above and will be omitted for simplicity purposes.

In a non-limiting example, the substrate 331 and the patterned structure 333 are both silicon nitride. The patterned structure 333 has —NH₂ surface groups which can react with DCS to form an intermediate layer 341 over the patterned structure 333. The intermediate layer 341 can be conformal or semi-conformal over the patterned structure 333. The intermediate layer 341 may have —SiH₂ surface groups.

Referring back to FIG. 2, In block 213, the chamber 110 is purged with a purge gas to remove unreacted DCS. In block 221, the aforementioned nitrogen precursor is introduced into the chamber 110 as the second reactant. A combination of N₂ and H₂ will be used herein as one example of the nitrogen precursor for illustrative purposes. The combination of N₂ and H₂ can be used to generate a nitrogen plasma in the chamber 110 to react with the intermediate layer 341 to form sufficient —NH₂ termination on silicon nitride surface. The nitrogen plasma can be generated at a first very high frequency (VHF) of 100 MHz to 300 MHz (e.g. 100 MHZ, 150 MHz, 200 MHz, 250 MHz, 300 MHz, or any value therebetween) to suppress ion incident energy and thus avoid film damage.

As a result in FIG. 3B, a material layer 343 is formed. More specifically, a Si—N bond is formed as a result of the reaction between the —SiH₂ surface groups and the nitrogen plasma. The material layer 343 can be conformal or semi-conformal over the patterned structure 333. The material layer 343 may have —NH₂ surface groups.

Referring back to FIG. 2, in block 223, the chamber 110 is purged with a purge gas to remove unreacted N₂ and H₂. In block 231, a helium plasma is generated in or provided for the chamber 110 to remove surface hydrogen termination around the top 335 of the patterned structure 333 to suppress film growth rate at the top 335 and thus suppress void formation. The helium plasma can be generated at a second VHF of 100 MHz to 300 MHz (e.g. 100 MHz, 150 MHz, 200 MHz, 250 MHz, 300 MHz, or any value therebetween) to obtain a more directional ion incident angle and thus allow for more flux into the top 335.

For example in FIG. 3C, a helium plasma represented by arrows can contain helium species such as He⁺ ions and/or He* radicals. The helium species can be delivered anisotropically towards the top 335 of the patterned structure 333. That is, the helium species can be substantially unidirectional along the Z direction, which is substantially perpendicular to the top 335. Consequently, hydrogen may desorb from —NH₂ surface groups at the top 335, relative to the sidewall 339 and the bottom 337. The material layer 343 at the top 335 may thus have —NH and/or —N* surface groups.

As discussed earlier, the patterned structure 333 can have a high aspect ratio of 3 to 20. Therefore, plasma conditions can be controlled so that the helium species do not significantly desorb hydrogen from —NH₂ surface groups at the bottom 337 or the sidewall 339, relative to the top 335. Additionally, another plasma containing other inert gas species may be used to modify the material layer 343 in alternative embodiments.

Referring back to FIG. 2, in block 233, the chamber 110 is purged with a purge gas to remove unreacted helium species. In block 241, a nitrogen plasma can be generated in or provided for the chamber 110 for film densification by conformal ion bombardment. The nitrogen plasma can be generated at a third VHF of 100 MHz to 300 MHz (e.g. 100 MHz, 150 MHz, 200 MHz, 250 MHz, 300 MHz, or any value therebetween) to obtain a more isotropic ion incident angle and thus allow for more flux into the sidewall 339.

As a result in FIG. 3D, a nitrogen plasma can be used to convert the material layer 343 to a densified layer 345. The nitrogen plasma can be isotropic or non-directional, thus affecting the material layer 343 at the top 335, the sidewall 339 and the bottom 337. The nitrogen plasma can provide N₂⁺ ions to remove hydrogen by a bridging reaction. For instance, a —Si—NH₂ surface group and an adjacent —Si—H surface group may lose one molecule of H₂ to form a —Si—NH—Si— bridge, as induced by the N₂⁺ ions. Such dehydrogenation and bridging can therefore densify and shrink the material layer 343.

Referring back to FIG. 2, in block 243, the chamber 110 is purged with a purge gas to remove unreacted nitrogen species. A first cycle of ALD is thus accomplished by blocks 211, 213, 221, 223, 231, 233, 241 and 243.

In one embodiment, the process 200 may then return to block 211 by introducing the silicon precursor into the chamber 110. As a result in FIG. 3E, an intermediate layer 351 can be formed over the densified layer 345. Since hydrogen has already been desorbed from the —NH₂ surface groups at the top 335, film growth at the top 355 will be suppressed, relative to the sidewall 339 and the bottom 337. Accordingly, the intermediate layer 351 have more —SiH₂ surface groups at the sidewall 339 and the bottom 337 than at the top 335. For instance, the intermediate layer 351 may have no —SiH₂ surface groups at the top 335. In addition, the intermediate layer 351 is thicker at the sidewall 339 and the bottom 337 than at the top 335. The process 200 can repeat the first cycle for at least one more time to form a film of a desired thickness. The film may be thicker at the sidewall 339 and the bottom 337 than at the top 335 due to different film growth rates. Particularly, suppressed film growth at the top 335 herein can prevent void formation for gap filling purposes (see e.g. FIG. 4B).

In another embodiment, the process 200 may return to block 231 after block 243, before eventually returning to block 211. That is to say, the first cycle may include an inner cycle including blocks 231, 233, 241 and 243. The inner cycle can repeatedly use the helium plasma and the nitrogen plasma to better suppress film growth at the top 335 as well as shrink the densified layer 345.

In yet another embodiment, a second cycle can include blocks 211, 213, 221, 223, 241 and 243. Film growth at the top 335 is not suppressed in the second cycle. The process 200 may repeatedly execute the first cycle and the second cycle in any sequence or order.

The process 200 can be terminated when a predetermined number of ALD cycles is finished, when a target local film thickness is reached, or when the patterned structure 333 has been filled or overfilled.

While SiN is shown herein for illustrative purposes, it should be understood that techniques herein are also applicable to other films including, but not limited to, silicon oxide, silicon oxynitride and silicon carbide. Accordingly in block 221, another precursor, such as an oxygen precursor and/or a carbon precursor, may be introduced into the chamber 110. In block 241, the nitrogen plasma may be substituted with an oxygen plasma, a carbon plasma or no plasma.

In some embodiments, the controller 140 may optionally be coupled to various components of the process 200 to receive inputs from and provide outputs to the components. For example, the controller 140 can be configured to receive gas flow rate data from blocks 211, 213, 221, 223, 231, 233, 241 and 243 as well as control gas flow rates in blocks 211, 213, 221, 223, 231, 233, 241 and 243. That is to say, the controller 140 can be configured to implement and monitor blocks 211, 213, 221, 223, 231, 233, 241 and 243. While not shown, the controller 140 can also be configured to determine when to terminate the process 200 by determining whether the predetermined number of ALD cycles is finished, when the target local film thickness is reached by measurement of the sensors 119, or when the patterned structure 333 has been filled or overfilled by measurement of the sensors 119. Of course, one or more functions of the controller 140 can also be manually accomplished.

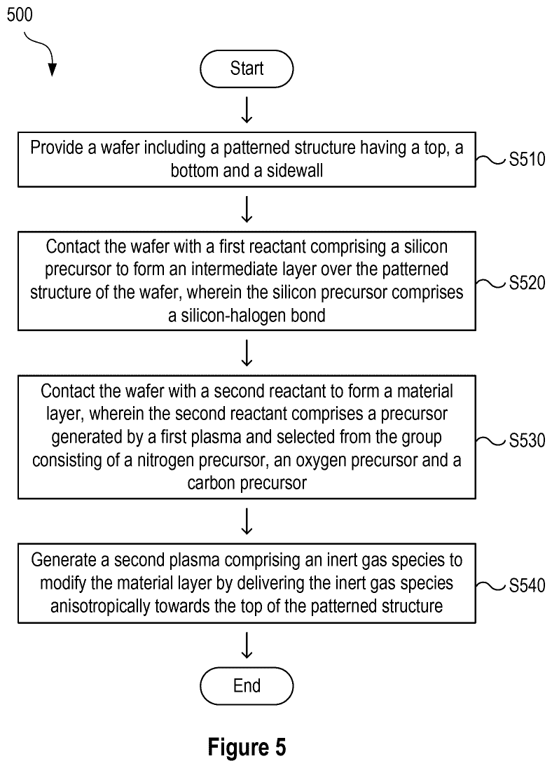

FIG. 5 shows a flow chart of a process 500 for manufacturing a semiconductor device (e.g. 300 and the like), in accordance with some embodiments of the present disclosure. At step S510, a wafer is provided that includes a patterned structure having a top, a bottom and a sidewall. At step S520, the wafer is contacted with a first reactant including a silicon precursor to form an intermediate layer over the patterned structure of the wafer. The silicon precursor includes a silicon-halogen bond. At step S530, the wafer is contacted with a second reactant to form a material layer. The second reactant includes a precursor generated by a first plasma and selected from the group consisting of a nitrogen precursor, an oxygen precursor and a carbon precursor. At step S540, a second plasma including an inert gas species is generated to modify the material layer by delivering the inert gas species anisotropically towards the top of the patterned structure. A film can be formed on the wafer by a cyclical deposition process including a cycle of step S520, step S530 and step S540.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of film deposition, the method comprising:
providing a wafer including a patterned structure having a top, a bottom and a sidewall; and
forming a film on the wafer by a cyclical deposition process comprising a cycle of:
contacting the wafer with a first reactant comprising a silicon precursor to form an intermediate layer over the patterned structure of the wafer, wherein the silicon precursor comprises a silicon-halogen bond;
contacting the wafer with a second reactant to form a material layer, wherein the second reactant comprises a precursor generated by a first plasma and selected from the group consisting of a nitrogen precursor, an oxygen precursor and a carbon precursor; and
generating a second plasma comprising an inert gas species to modify the material layer by delivering the inert gas species anisotropically towards the top of the patterned structure.

2. The method of claim 1, wherein:
the silicon precursor comprises a chlorosilane represented by a formula of SiₙHₓCl_{y}, where
n is 1, 2, 3 or 4,
x is an integer of 0 or more,
y is an integer of 1 or more, and
x+y=2n+2.

3. The method of claim 2, wherein:
the silicon precursor includes at least one selected from the group consisting of H₃SiCl, dichlorosilane (DCS), tetrachlorosilane, pentachlorodisilane (PCDS), hexachlorodisilane (HCDS) and octachlorotrisilane.

4. The method of claim 1, wherein the cycle further comprises:
generating a third plasma comprising nitrogen ions to modify the material layer by delivering the nitrogen ions isotropically towards the patterned structure.

5. The method of claim 4, wherein:
the nitrogen ions are configured to densify and shrink the film.

6. The method of claim 4, wherein the cycle further comprises repeating for at least one more time:
generating the second plasma; and
generating the third plasma.

7. The method of claim 4, wherein:
the third plasma further comprises argon (Ar).

8. The method of claim 1, wherein:
the second plasma comprises helium (He), and
the inert gas species comprises He⁺ ions, He* radicals or a combination thereof.

9. The method of claim 8, wherein:
the inert gas species is substantially unidirectional and substantially perpendicular to the top of the patterned structure.

10. The method of claim 9, wherein:
the inert gas species is configured to suppress film deposition at the top of the patterned structure.

11. The method of claim 9, wherein:
the inert gas species is configured to suppress film deposition at the top of the patterned structure without suppressing film deposition at the bottom of the patterned structure.

12. The method of claim 1, wherein:
the second plasma comprises no nitrogen.

13. The method of claim 1, wherein:
the second reactant comprises N₂H₂, NF₃, NH₃, N₂H₄ or a combination of N₂ and H₂.

14. The method of claim 1, wherein:
the cyclical deposition process comprises atomic layer deposition.

15. The method of claim 1, wherein:
the cyclical deposition process includes repeating the cycle for at least one more time.

16. The method of claim 15, wherein:
the film is thinner at the top of the patterned structure than at the bottom and the sidewall of the patterned structure.

17. The method of claim 1, wherein:
the patterned structure of the wafer comprises at least one surface group selected from the group consisting of —SiH, —SiOH and —SiNH₂.

18. The method of claim 1, wherein:
the material layer comprises one selected from the group consisting of silicon nitride, silicon oxide, silicon oxynitride and silicon carbide.

19. The method of claim 1, wherein:
the top and the bottom of the patterned structure are substantially parallel to each other, and
a ratio of a depth of the patterned structure to a width of the bottom is in a range of 3 to 20.

20. An apparatus, comprising a controller including a processor that is programmed to:
provide a wafer including a patterned structure having a top, a bottom and a sidewall; and
form a film on the wafer by a cyclical deposition process comprising a cycle of:
contacting the wafer with a first reactant comprising a silicon precursor to form an intermediate layer over the patterned structure of the wafer, wherein the silicon precursor comprises a silicon-halogen bond;
contacting the wafer with a second reactant to form a material layer, wherein the second reactant comprises a precursor generated by a first plasma and selected from the group consisting of a nitrogen precursor, an oxygen precursor and a carbon precursor; and
generating a second plasma comprising an inert gas species to modify the material layer by delivering the inert gas species anisotropically towards the top of the patterned structure.
